(19) United States
(12) Patent Application Publication
(10) Pub. No.: US 2007/0278479 A1
(43) Pub. Date: Dec. 6, 2007

(54) N-Doping Of Organic Semiconductors

(76) Inventors: Ansgar Werner, Dresden (DE); Martin Pfeiffer, Dresden (DE); Kentaro Harada, Dresden (DE); Karl Leo, Dresden (DE); C. Michael Elliot, Fort Collins, CO (US)

Correspondence Address: SUTHERLAND ASBILL & BRENNAN LLP, 999 PEACHTREE STREET, N.E., ATLANTA, GA, 30309, US

(21) Appl. No.: 10/595,319

(22) PCT Filed: Oct. 8, 2004
(86) PCT No.: PCT/DE04/02247

§ 371 Date: Feb. 6, 2007

(30) Foreign Application Priority Data
Oct. 10, 2003 (DE) DE 103 856.6-33

(51) Int. Cl. H01L 51/30; C04B 35/00; H01L 51/40

(52) U.S. Cl. 257/40; 252/62.3 Q; 438/99; 257/E51.025

(57) ABSTRACT

The invention relates to a process for producing doped organic semiconductor materials with an elevated charge carrier density and effective charge carrier mobility by doping, in which the doping agent is substantially produced by electrocrystallization in a first step, the doping agent is selected from a group of organic compounds with a low oxidation potential, and in which an organic semiconductor material is doped with the doping agent in a second step. Furthermore, the invention relates to doped organic semiconductor materials with an elevated charge carrier density and effective charge carrier mobility produced by the aforementioned process. Furthermore, the invention relates to an organic diode comprising doped organic semiconductor materials produced in accordance with the aforementioned process.

The invention is relates to doped, organic semiconductor materials with elevated charge carrier density and effective charge carrier mobility as well as to a process of manufacturing them.

The charge carrier density can be significantly elevated in organic solids (and therewith the conductivity) by doping hole transport layers with a suitable acceptor material (p-doping) or electron transport layers with a donor material (n doping). Furthermore, applications can be expected, in analogy with the experience with inorganic semiconductors, that are based on the use of p- and n-doped layers in a structural element and that would not be conceivable otherwise. U.S. Pat No. 5,093,698 describes the use of doped charge carrier transport layers (p-doping of the hole transport layer by admixing acceptor-like molecules, n-doping of the electron transport layer by admixing donator-like molecules) in organic light-emitting diodes.

In contrast to doping processes with inorganic materials that entail on the one hand diffusion problems of the doping material used in the form of relatively small molecules and/or atoms and on the other hand undesired and unpredictable chemical reactions between matrix and doping material, the use of organic molecules as doping material has proved to be advantageous. In general, organic doping agents have a greater stability of the structural elements and the diffusion plays a subordinate part so that the defined production of sharp transitions from p-doped to n-doped areas is simplified. In the case of a doping with organic molecules a charge transfer between matrix and doping material exclusively occurs; however, no chemical bonding is formed between them. Furthermore, the doping concentration for obtaining a high conductivity of the doped layer in the case of organic doping agents is advantageously at least one order of magnitude below that of inorganic doping agents.

The doping of organic semiconductor materials with organic compounds is substantially known in two different processes, namely, the doping with air-stable doping agents and the doping with a stable precursor substance for releasing a doping agent that is not stable in air.

In the case of doping with air-stable doping agents the relevant compounds exhibit disadvantageous properties. For example, air-stable, organic doping agents have an insufficiently low oxidation potential for being used as technically relevant electron transport materials with a low reduction potential.

As regards a doping with a stable precursor substance in order to release a doping agent that is not stable in air, the released compounds can have a sufficiently low oxidation potential for being used as electron transport materials that are used in organic solar cells but not for being used as organic light-emitting diodes.

Therefore, the present invention has the basic task of improving the electrical properties of (opto-) electronic structural elements such as, e.g., organic light-emitting diodes or solar cells based on organic semiconductor materials. In particular, the ohmic losses in charge carrier transport layers should be reduced and the contact properties improved.

This task is solved by the production process according to Claim 1, by the product obtainable from it according to Claim 11, and by a diode obtainable using the product according to Claim 18.

The use of readily accessible organic salts as initial substances for organic doping agents is made possible by the process for producing doped organic semiconductor materials with an increased charge carrier density and effective charge carrier mobility by doping with a doping agent, in which the doping agent is produced in a first step by electrocrystallization, the doping agent is selected from a group of organic compounds with a low oxidation potential, and in which an organic semiconductor material is doped with the doping agent in a second step. Therefore, the process makes available a new and further class of doping agents that has preferred properties compared to the previously used materials, especially as regards the parameter of the oxidation potential.

Compounds with a low oxidation potential can possibly still be stable in air but as a rule are not. In general, compounds with an oxidation potential in a range of +0.3 to 0 V against SCE are still stable in air but on the other hand compounds with an oxidation potential less than 0 V against SCE are no longer to be regarded as stable in air. The lower the oxidation potential of a compound, the less stable is the compound in air.

The invention provides that a salt of the organic doping agent is used as educt for the electrocrystallization. The organic doping agent is typically present as a singly or multiply charged cation in the salt of the educt. Thus, in this instance a singly or multiply charged cation is used in the educt salt of the organic doping agent. It is possible to obtain the doping agent contained in a salt form as ion in the neutral state as a pure intermediate product by the electrocrystallization.

It is in the sense of the invention that the doping agent is an uncharged organic compound. The use of organic doping agents compared to inorganic doping agents is advantageous as regards a lesser undesired diffusion of the doping agents in the matrix, greater stability and lesser expense as regards the provision of educt.

The doping agent can be crystallized out on a working electrode and subsequently harvested on the working electrode. The doping agent is customarily only poorly soluble in the solvent used in the electrocrystallization and can therefore precipitate almost completely on the electrode. During the harvesting, the doping agent, that is typically unstable in air, can be stored and optionally transported directly or after drying under an atmosphere of protective gas.

In addition, the doping agent can be purified after the harvesting on a working electrode in an additional intermediate step. The purification can be, e.g., a drying or some other type of purification known in the state of the art. After the purification has taken place the doping agent is then held ready for a further step for processing with the semiconductor material under an atmosphere of inert gas. Thus, the doping agent is available in an extremely pure state.

The doping agent is preferably mixed into the organic semiconductor material in the second step.

It is provided that a compound with an oxidation potential of less than 0 V against NHE is used as doping agent. A compound with an oxidation potential in the range of −0.5 V against NHE to −2.5 V against NHE is preferably used as doping agent. Bis(2,2′-terpyridine)ruthenium or tris(4,4′,5,5′-tetramethyl-2,2′-bipyridine)chromium is especially preferably used as doping agent, bis(2,2′-terpyridine)ruthenium having an oxidation potential of −1.28 V against NHE and tris(4,4′,5,5′-tetramethyl-2,2′-bipyridine)chromium having an oxidation potential of −1.44 V against NHE. For example, fullerene C₆₀ (with a reduction potential of −0.98 V against Fc/Fc⁺), tris(8-hydroxyquinolinato) aluminum (with a reduction potential of −2.3 V against Fc/Fc⁺), bathophenathroline (with an electron affinity of 3.0 eV) or phthalocyanine zinc (with a reduction potential of approximately −0.65 V against NHE) are used as organic semiconductors without being limited to them.

A doped, organic semiconductor material with elevated charge carrier density and effective charge carrier mobility can be produced with a process in accordance with the invention.

The semiconductor material is preferably doped with bis(2,2′-terpyridine)ruthenium. Alternatively, the semiconductor material can be doped with tris(4,4′,5,5′-tetramethyl-2,2′-bipyridine)chromium.

It is provided that the matrix of the semiconductor material consists substantially of fullerene. Alternatively, the matrix of the semiconductor material can consist substantially of phthalocyanine zinc.

It is especially preferably provided that the semiconductor material has a conductivity of approximately 10⁻¹ s/cm at room temperature, the matrix of the semiconductor material consisting substantially of fullerene and the semiconductor material being doped with bis(2,2′-terpyridine)ruthenium. Alternatively, the semiconductor material can have a conductivity of approximately 10⁻⁶ s/cm at room temperature, the matrix of the semi conductive material consisting substantially of phthalocyanine zinc and the semiconductor material being doped with bis(2,2′-terpyridine)ruthenium.

The doped organic semiconductor material is advantageously a component of an organic diode, the diode being from a metal-isolator-N-doped semiconductor (min) transition or a p-doped semiconductor-isolator-N-doped semiconductor (pin). The diode can then have a rectification ratio of at least 10⁵. Alternatively or additionally, the diode can have a built-in voltage of approximately 0.8 V. A built-in voltage of 0.8 V is especially advantageous for the manufacture of organic solar cells.

Further advantageous embodiments result from the subclaims.

The invention is explained in the following using an exemplary embodiment shown in the drawing.

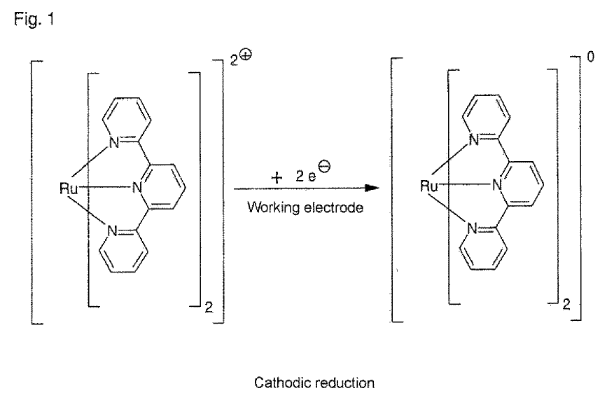

FIG. 1 shows an educt cation and the neutral complex obtainable from it in accordance with the process of the invention.

Bis(2,2′-terpyridine) ruthenium ([Ru(terpy)]) is used as organic doping agent in a process in accordance with the invention for producing doped organic semiconductor materials with elevated charge carrier density and effective charge carrier mobility by doping with a doping agent. To this end, the neutral ruthenium complex is produced by electrocrystallization in an electrochemical cell from its salt. The salt is a conventional compound in which the complex is present with a double positive charge. The complex [Ru(terpy)]²⁺(PF₆)₂ is used as salt.

The neutral form of the complex—[Ru(terpy)]⁰—is produced during the electrochemical reduction of the salt by receiving two electrons by the cation complex [Ru(terpy)]²⁺. The neutral complex [Ru(terpy)]⁰ is poorly soluble in the solvent used in the electrocrystallization and therefore precipitates on the working electrode in the electrochemical cell. The neutral complex has a very low oxidation potential and is therefore very sensitive to oxygen and other contaminants. Accordingly, the electrochemical reduction must be carried out under protective gas and under the observation of strict purity criteria for the solvent used. The neutral complex [Ru(terpy)]⁰ is subsequently harvested and filled into ampoules that are then welded under protective gas.

An evaporator source is then filled with this material under the exclusion of air and oxygen. Doped coatings are produced by the mixing evaporation of matrix and doping agent or by some other process.

Conductivities of 10⁻¹ s/cm at room temperature are achieved when using fullerene C₆₀ as matrix. This is one order of magnitude greater than when using previously known organic doping agents. The use of phthalocyanine zinc as matrix achieves a conductivity of 10⁻⁶ s/cm. It was previously not possible to dope this matrix with organic donors since the reduction potential of the matrix is too low. In contrast thereto, the conductivity of non-doped phthalocyanine zinc is only 10⁻¹⁰ s/cm.

Organic diodes of the metal-insulator-N-doped semiconductor (min) type are produced (on the base of phthalocyanine zinc) with the aid of these new donors. These diodes show a rectification ratio of 10⁵ and greater and a high built-in voltage of 0.8 V. A built-in voltage of 0.8 V is especially advantageously for the manufacture of organic solar cells.

Furthermore, the demonstration of a p-n transition with organic doping agents in which the same semiconductor material was used for the p-doped and the n-doped side (homo-p-n transition) was successful for the first time.

1. A process for the production of doped, organic semiconductor materials with elevated charge carrier density and effective charge carrier mobility by doping with a doping agent, in which the doping agent is substantially produced by electro-crystallization in a first step, the doping agent is selected from a group of organic compounds with a low oxidation potential, and in which an organic semiconductor material is doped with the doping agent in a second step.

2. The process according to claim 1, characterized in that a salt of the organic doping agent is used as educt for the electro-crystallization.

3. The process according to claim 2, characterized in that a singly or multiply charged cation is used in the educt salt of the organic doping agent.

4. The process according to claim 1, characterized in that an uncharged organic compound is used as doping agent.

5. The process according to claim 1, characterized in that the doping agent is crystallized out on a working electrode and is subsequently harvested on the working electrode.

6. The process according to claim 5, characterized in that the doping agent is purified in an intermediate step after the harvesting on a working electrode during the electro-crystallization.

7. The process according to claim 1, characterized in that a compound with an oxidation potential of less than 0 V against NHE is used as doping agent.

8. The process according to claim 7, characterized in that a compound with an oxidation potential in a range of −0.5 V against NHE to −2.5 V against NHE is used as doping agent.

9. The process according to claim 1, characterized in that bis(2,2′-terpyridine)ruthenium is used as doping agent.

10. The process according to claim 1, characterized in that tris(4,4′,5,5′-tetramethyl-2,2′-bipyridine)chromium is used as doping agent.

11. Doped, organic semiconductor material with elevated charge carrier density and effective charge carrier mobility, produced by a process in accordance with claim 1.

12. The doped, organic semiconductor material with elevated charge carrier density and effective charge carrier mobility according to claim 11, characterized in that the semiconductor material is doped with bis(2,2′-terpyridine)ruthenium.

13. The doped, organic semiconductor material with elevated charge carrier density and effective charge carrier mobility according to claim 11, characterized in that the semiconductor material is doped with tris(4,4′,5,5′-tetramethyl-2,2′-bipyridine)chromium.

14. The doped, organic semiconductor material with elevated charge carrier density and effective charge carrier mobility according to claim 1, characterized in that the matrix of the semiconductor material contain fullerene.

15. The doped, organic semiconductor material with elevated charge carrier density and effective charge carrier mobility according to claim 11, characterized in that the matrix of a semiconductor material contains phthalocyanine zinc.

16. The doped, organic semiconductor material with elevated charge carrier density and effective charge carrier mobility according to claim 11, characterized in that the semiconductor material has a conductivity of approximately 10-1 s/cm at room temperature, that the matrix of the semiconductor material contains fullerene and that the semiconductor material is doped with bis(2,2′-terpyridine)ruthenium.

17. The doped, organic semiconductor material with elevated charge carrier density and effective charge carrier mobility according to claim 11, characterized in that the semiconductor material has a conductivity of approximately 10−6 S/cm at room temperature, that the matrix of the semiconductor material contains phthalocyanine zinc and that the semiconductor material is doped with bis(2,2′-terpyridine)ruthenium.

18. A diode consisting of doped, organic semiconductor material with elevated charge carrier density and effective charge carrier mobility, characterized in that the diode comprises doped, organic semiconductor material according to claim 11.

19. The diode according to claim 18, characterized in that the diode is a metal-isolator-N-doped semiconductor (min).

20. The diode according to claim 19, characterized in that the diode is a p-doped semiconductor-isolator-N-doped semiconductor (pin).

21. The diode according to claim 18, characterized in that the diode has a rectification ratio of at least 10⁵.

22. The diode according to claim 18, characterized in that the diode has a built-in voltage of approximately 0.8 V.
